(19) United States
(12) Patent Application Publication
(10) Pub. No.: US 2021/0259137 A1
(43) Pub. Date: Aug. 19, 2021

(54) ELECTRONIC DEVICE

(71) Applicant: SHARP KABUSHIKI KAISHA, Sakai City (JP)

(72) Inventors: HIDENORI KUWAJIMA, Sakai City (JP); TOMOYA IDE, Sakai City (JP); HIROKI TANABE, Sakai City (JP)

(21) Appl. No.: 17/175,346

(22) Filed: Feb. 12, 2021

(30) Foreign Application Priority Data
Feb. 14, 2020 (JP) 2020-023828

(51) Int. Cl. H05K 7/20; H01L 23/373; H01L 23/367; G01K 7/42; G01K 7/16; G05D 23/24; G05D 23/19

(52) U.S. Cl. CPC H05K 7/20481; H05K 7/205; H01L 23/3735; G05D 23/1928; G01K 7/42; G01K 7/16; G05D 23/24; H01L 23/367

(57) ABSTRACT

An electronic device comprises an electronic component serving as a heat source; a first substrate on which the electronic component is disposed; a heat dissipation member that covers, with a first heat insulation layer in between, an area including a region of the first substrate, at which the electronic component is disposed, and being on a front side or a rear side of the first substrate; a housing that accommodates at least the first substrate and the heat dissipation member; a second substrate that faces the heat dissipation member across a second heat insulation layer in the housing; and a thermistor disposed on the second substrate.

### BACKGROUND

### 1. Field

An aspect of the present disclosure relates to an electronic device.

### 2. Description of the Related Art

In recent years, with improvement of performance of electronic devices, in particular, small and thin electronic devices such as smartphones, there have been growing concerns about a rise in temperature of a housing surface of an electronic device at the time of use or the like. Particularly, in new use cases such as 5G communication or recording by an 8K camera, the amount of power consumed by a CPU, a GPU, or the like is especially large, and therefore the temperature of the electronic device becomes locally high, resulting in generation of a heat spot having excessively high temperature.

For example, Japanese Unexamined Patent Application Publication No. 2016-121985 describes a configuration in which a processor 5 disposed on a substrate of an electronic device acquires a first measurement value from a temperature sensor disposed on the substrate, and the processor calculates the surface temperature of a housing on the basis of transfer functions and the first measurement value.

However, since the technique described in Japanese Unexamined Patent Application Publication No. 2016-121985 provides a structure in which the temperature sensor is disposed on the substrate, when a different component on the substrate generates heat, the heat generated by the different component affects the temperature sensor.

Thus, there may be a problem that loss of a correlation between the surface temperature of the housing and temperature of a heat source on the substrate makes it difficult to accurately calculate the surface temperature and that a heat spot having excessively high temperature is generated.

When an arithmetic load of a CPU, a GPU, or the like is immoderately reduced to suppress generation of a heat spot, there is a problem that, for example, delay of a mathematical operation is unnecessarily caused, and performance is unnecessarily degraded.

An aspect of the disclosure is made in view of the aforementioned problems and provides an electronic device that accurately detects temperature of a heat spot in a housing.

### SUMMARY

To address the aforementioned problems, an electronic device according to an aspect of the disclosure includes: an electronic component serving as a heat source; a first substrate on which the electronic component is disposed; a heat dissipation member that covers, with a first heat insulation layer in between, an area including a region of the first substrate, at which the electronic component is disposed, and being on a front side or a rear-side of the first substrate; a housing that accommodates at least the first substrate and the heat dissipation member; second substrate that faces the heat dissipation member across a second heat insulation layer in the housing; and a thermistor disposed on the second substrate.

### BRIEF DESCRIPTION OF THE DRAWINGS

FIG. 1 is a sectional view of a portion of an electronic device according to a first embodiment of the disclosure;

FIG. 2 is a front view of a holding member, a second substrate, and a thermistor that are provided in the electronic device according to the first embodiment of the disclosure;

FIG. 3 is an enlarged sectional view of a portion of the electronic device in an area A1 or an area A2 in FIG. 1

FIG. 4 is a sectional view of an example of an electronic component mounted on the electronic device according to the first embodiment of the disclosure;

FIG. 5 is a sectional view of the side surface of the electronic device according to the first embodiment of the disclosure;

FIG. 6 is a view for explaining heat capacity and thermal resistance in the electronic device according to the first embodiment of the disclosure;

FIG. 7 is a sectional view of a portion of an electronic device according to a second embodiment of the disclosure; and

FIG. 8 is a perspective view illustrating a holding member and a thermistor that are provided in the electronic device according to the second embodiment of the disclosure.

### DESCRIPTION OF THE EMBODIMENTS

### First Embodiment

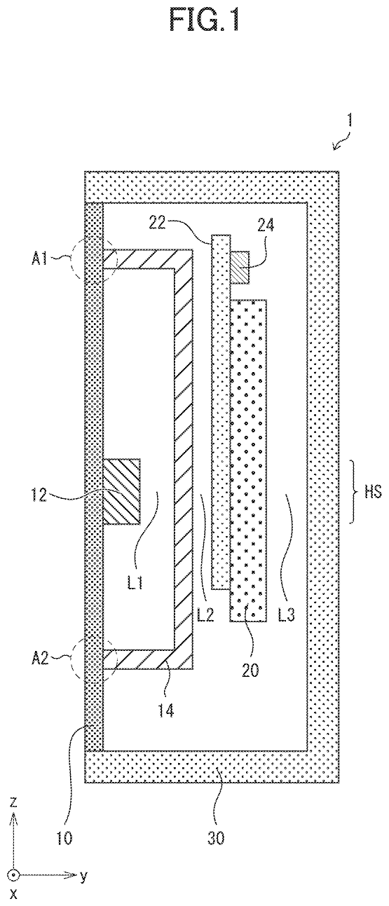

A first embodiment of the disclosure will be described below in detail with reference to FIGS. 1 to 6. Note that examples of an electronic device according to an aspect of the disclosure include a smartphone. In addition to the smartphone, various products including a personal computer, a game machine, a tablet terminal, and a household appliance such as a refrigerator are assumed to be the electronic device according to the aspect of the disclosure.

FIG. 1 is a sectional view of an electronic device 1 according to the present embodiment. As illustrated in FIG. 1, the electronic device 1 includes a first substrate 10, an electronic component 12, a heat dissipation member 14, a holding member 20, a second substrate 22, a thermistor 24, and a housing 30.

The electronic device 1 controls an arithmetic load of the electronic component 12 by referring to temperature detected by the thermistor 24 and thereby manages temperature of the housing 30 to be less than or equal to given temperature. Therefore, it is desirable that a value of the temperature of the housing 30 is as close as possible to that of the temperature detected by the thermistor 24. Note that processing of the above-described temperature management may be performed mainly by, for example, the electronic component 12 or may be performed by another member.

Moreover, the configuration may be such that the electronic device 1 estimates the temperature of the housing 30 by adding or subtracting an offset to or from the temperature detected by the thermistor 24.

In the following description, as illustrated in FIG. 1, a direction normal to the first substrate is sometimes referred to as the y-direction, and directions parallel to the first substrate are sometimes referred to as the x-direction and the z-direction. In addition, a direction from the first substrate 10 to the second substrate 22 is set as the positive direction of the y-direction.

The first substrate 10 is, for example, a rigid substrate. A specific configuration example of the first substrate 10 will be described later with reference to a different drawing, m addition to the electronic component 12 described below, other components or elements can be disposed on the first substrate 10.

### Electronic Component

The electronic component 12 is disposed on the first substrate 10. The electronic component 12 can be a heat source, and whether or not the electronic component 12 generates heat and to what degree the electronic component 12 generates heat vary in accordance with a usage mode.

The electronic component 12 is configured to include a system on chip (SoC) including an integrated circuit such as a central processing unit (CPU) or a graphical processing unit (GPU). However, the present embodiment is not limited thereto, and another electronic component that can be a heat source may be the electronic component 12. A specific configuration example of the electronic component 12 will be described later with reference to a different drawing.

Note that, in FIG. 1, a position of the electronic component 12 on the first substrate 10 and a size of the electronic component 12 are merely exemplification and do not limit the present embodiment.

### Heat Dissipation Member and First Heat Insulation Layer

As illustrated in FIG. 1, the heat dissipation member 14 covers, with a first heat insulation layer L1 in between, an area including a region of the first substrate 10, at which the electronic component 12 is disposed. The heat dissipation member 14 is, for example, a plate member.

Here, when it is assumed that a surface of the first substrate 10, on which the electronic component 12 is disposed, is referred to as a front surface, and a surface thereof on which the electronic component 12 is not disposed is referred to as a rear surface, the heat dissipation member 14 covers the front surface of the first substrate 10 in the example of FIG. 1. However, the present embodiment is not limited thereto, and the configuration may be such that the heat dissipation member 14 covers the rear surface of the first substrate 10. More specifically, the configuration may be such that, in FIG. 1, the electronic component 12 is disposed on a surface of the first substrate 10, which is opposite to the surface the heat dissipation member 14 covers as illustrated in FIG. 1.

Moreover, as illustrated in areas A1 and A2 indicated by circles in FIG. 1, the heat dissipation member 14 is connected to the first substrate 10. Thus, the heat dissipation member 14 is able to efficiently conduct, to the heat dissipation member 14, heat generated by the electronic component 12 and conducted through the first substrate 10 and to dissipate the heat.

The first heat insulation layer L1 is, for example, an air. As another example of the first heat insulation layer L1, a heat insulation member may be used. More specifically, the configuration may be such that a heat insulation member having a heat insulating property is disposed between the electronic component 12 and the heat dissipation member 14. Moreover, the configuration may be such that the first heat insulation layer L1 includes both a heat insulation member and an air layer.

A material constituting the heat dissipation member 14 is formed of a material having thermal conductivity higher than or equal to thermal conductivity of the first substrate 10. Here, the thermal conductivity of the first substrate 10 is thermal conductivity of a body of the first substrate 10, which is mainly formed of a resin, and all metal wires which are provided in the first substrate 10. The thermal conductivity is typically about 20 W/mK.

As described below, since many wires and vias (thermal vias) which are formed of a material having high electrical conductivity and thermal conductivity are provided near the electronic component 12 on the first substrate 10, thermal conductivity from the electronic component 12 to the heat dissipation member 14 is higher than the thermal conductivity of the entire first substrate 10. The thermal conductivity from the electronic component 12 on the first substrate 10 to the heat dissipation member 14 is three times or more the thermal conductivity of the entire substrate. Furthermore, when the structure is devised by using sufficient copper for the substrate or by providing thermal vias as many as possible, the thermal conductivity from the electronic component 12 to the heat dissipation member 14 is five to ten times the thermal conductivity of the entire substrate. Accordingly, it may be more desirable that the material constituting the heat dissipation member 14 is formed of a material having thermal conductivity higher than or equal to the thermal conductivity from the electronic component 12 on the first substrate 10 to the heat dissipation member 14. For example, the heat dissipation member may be constituted by a material having thermal conductivity of 50 W/mK or more. Specific examples of the material of the heat dissipation member 14 include a material containing copper, gold, silver, aluminum, or the like, but the material is not limited thereto.

As described above, the heat dissipation member 14 is connected to the first substrate 10. Heat generated by the electronic component 12 is spread in the first substrate 10 mainly through the wires disposed inside and is dissipated from the first substrate 10. Furthermore, the heat spread in the first substrate 10 is spread in the entire heat dissipation member 14 from a connection portion of the first substrate 10 and the heat dissipation member 14. The heat spread throughout the entire heat dissipation member 14 is spread in a large area of the housing 30 and is also dissipated from the surface of the housing 30.

Since the heat dissipation member 14 is constituted by a material having high thermal conductivity as described above, the heat transferred to the heat dissipation member 14 is quickly and smoothly spread in the heat dissipation member 14, and it is therefore possible to suppress a local rise in temperature of the heat dissipation member 14 in an area facing the electronic component 12. Thus, it is possible to suppress generation of a heat spot (HS), which has excessively high temperature in an area near the electronic component 12, also in the surface of the housing 30.

### Holding Member, Second Substrate, and Second Heat Insulation Layer

The holding member 20 holds the second substrate 22. The holding member 20 is formed of, for example, a resin material, but the present embodiment is not limited thereto.

The second substrate 22 is held by the holding member 20. The second substrate 22 is, for example, a flexible printed circuit board, but the present embodiment is not limited thereto.

As illustrated in FIG. 1, in the housing 30, the second substrate 22 faces a main surface of the heat dissipation member 14 across a second heat insulation layer L2. That is, the second substrate 22 is disposed on a side of the heat dissipation member 14 opposite to the first substrate 10 is disposed so as to face the heat dissipation member 14 with the second heat insulation layer L2 in between.

Moreover, as illustrated in FIG. 1, the second substrate 22 is disposed on the surface of the holding member 20 on a first substrate 10 side. By disposing the second substrate 22 in this manner, it is possible to more suitably make the temperature detected by the thermistor 24 close to the temperature of the housing 30.

The second heat insulation layer L2 is, for example, an air. As another example of the second heat insulation layer L2, a heat insulation member may be used. More specifically, the configuration may be such that a heat insulation member having a heat insulating property is disposed between the heat dissipation member 14 and the second substrate 22. Moreover, the configuration may be such that the second heat insulation layer L2 includes both a heat insulation member and an air layer.

### Thermistor

The thermistor 24 is disposed on the second substrate 22. As illustrated in FIG. 1, the thermistor 24 is disposed, for example, on the surface of the second substrate 22, which is opposite to the first substrate 10 side.

By disposing the thermistor 24 on the surface of the second substrate 22, which is opposite to the first substrate 10 side, in this manner, it is possible to more suitably make the temperature detected by the thermistor 24 close to the temperature of the housing 30.

Moreover, as illustrated in FIG. 1, the thermistor 24 is disposed on the second substrate 22 such that the thermistor 24 is not in contact with the holding member 20. In other words, the thermistor 24 is disposed apart from the holding member 20. When the thermistor 24 is disposed apart from the holding member 20, the thermistor 24 is less likely to be affected by a change in temperature of the holding member 20, and it is therefore possible to more suitably calculate the temperature of the housing 30 by referring to the temperature detected by the thermistor 24.

### Housing and Third Heat Insulation Layer

As illustrated in FIG. 1, the housing 30 accommodates the first substrate 10, the heat dissipation member 14, the holding member 20, and the second substrate 22.

Moreover, as illustrated in FIG. 1, a third heat insulation layer L3 is disposed between the holding member 20 and the housing 30. Here, the third heat insulation layer L3 is, for example, an air. As another example of the third heat insulation layer L3, a heat insulation member may be used. More specifically, the configuration may be such that a heat insulation member having a heat insulating property is disposed between the holding member 20 and the housing 30. Moreover, the configuration may be such that the third heat insulation layer L3 includes both a heat insulation member and an air layer.

With the aforementioned configuration, it is possible to suppress an excessive rise in temperature of the housing 30.

### Specific Example of Disposition of Thermistor

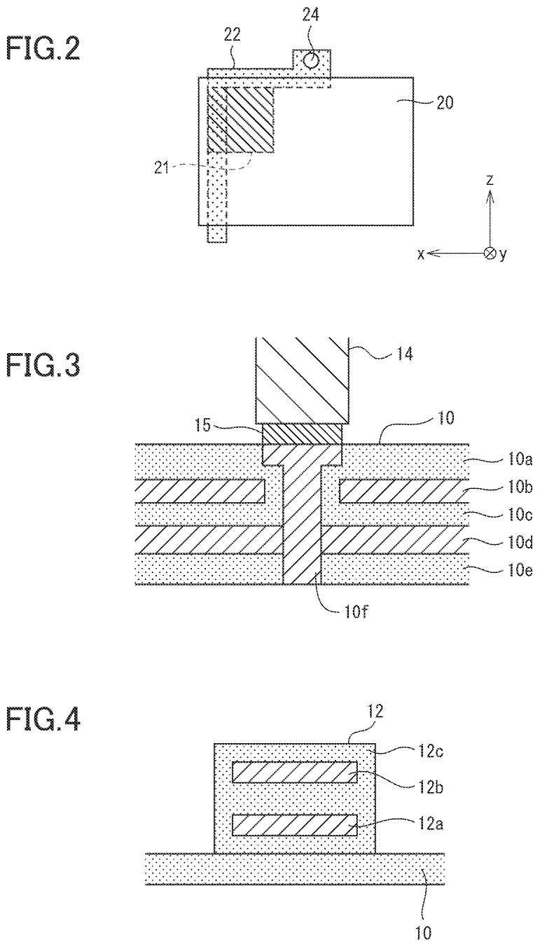

Subsequently, a specific example of disposition of the thermistor 24 will be described with reference to FIG. 2. FIG. 2 is a front view of the holding member 20, the second substrate 22, and the thermistor 24, which is viewed in the y-direction from the positive direction to the negative direction. In FIG. 2, an area 21 is an area of the holding member 20, which faces the electronic component 12, as an example.

As illustrated in FIG. 2, the second substrate 22 is disposed, for example, so as to at least partially overlap the area 21. Moreover, as illustrated in FIG. 2, the second substrate 22 is, for example, a strip-shaped substrate having a bent portion, and the thermistor 24 is, in an edge of the second substrate, disposed apart from the holding member 20 so as not to be in contact with the holding member 20.

Moreover, as illustrated in FIGS. 1 and 2, the thermistor 24 is disposed at a position which is not immediately above the electronic component 12 in the y-direction. In other words, at least one of the position of the thermistor 24 in the x-axis and the position in the z-axis differs from the position of the electronic component 12 in the x-axis or the position in the z-axis. Thereby, it is possible to avoid a problem that the thermistor 24 is excessively affected by heat from the electronic component 12.

In the electronic device 1 configured as above, the thermistor 24 is disposed not on the first substrate 10 on which the electronic component 12 is disposed but on the second substrate 22. Thus, the thermistor 24 is not directly affected by a change in temperature of the electronic component 12.

Further, since the thermistor 24 is disposed at the position which is not immediately above the electronic component 12 in the y-direction as described above, the thermistor 24 is not directly affected by the change in temperature of the electronic component 12.

Moreover, in the electronic device 1, the heat generated by the electronic component 12 is transferred, for example, through the substrate 10 or the first heat insulation layer L1 and transferred to the heat dissipation member 14. Then, the heat is transferred to the second substrate 22 from the heat dissipation member 14 through the second heat insulation layer L2.

Therefore, the electronic device 1 is able to suitably calculate the temperature of the housing 30 by referring to the temperature detected by the thermistor 24. Accordingly, the electronic device 1 is able to accurately detect the temperature of the housing 30.

The electronic device 1 is able to finely control performance of the electronic component 12 serving as a heat source in accordance with the detected temperature of the housing 30 and is thus able to enable the electronic component 12 to exert positive performance, while suppressing temperature of the surface of the housing 30 so as not to exceed temperature of safety standards. Thus, the electronic device 1 is able to provide comfortable operability to a user.

### Connection of First Substrate and Heat Dissipation Member

Subsequently, an example of connection of the first substrate 10 and the heat dissipation member 14 will be described with reference to FIG. 3.

FIG. 3 is an enlarged sectional view of a portion in the area A1 indicated by a circle in FIG. 1. A similar configuration is provided also in a portion in the area A2 indicated by a circle in FIG. 1.

As illustrated in FIG. 3, the first substrate 10 is configured by laminating a first resin layer 10a, a wiring layer 10b, a second resin layer 10c, a ground layer 10d, and a third resin layer 10e. As illustrated in FIG. 3, the first substrate 10 may include a via 10f that connects the front surface and the rear surface of the first substrate 10.

The wiring layer 10b is a layer in which a wire electrically connecting the electronic component and an element, which are mounted on the first substrate, to each other is disposed. The wiring layer 10b is formed of a material having conductivity, such as copper. As illustrated in FIG. 3, the wiring layer 10b is disposed between the first resin layer 10a and the second resin layer 10c.

The ground layer 10d is a layer in which a ground connected to the electronic component or the element which is mounted on the first substrate 10 is disposed. The ground layer 10d is formed of a material having conductivity, such as copper. As illustrated in FIG. 3, the ground layer 10d is disposed between the second resin layer 10c and the third resin layer 10e. However, the structure illustrated in FIG. 3 is an example of a structure of a multilayer substrate, and a structural order and the number of layers of the resin layers, the wiring layer, and the ground layer are not limited to the structure illustrated in FIG. 3.

In the via 10f, the interior of a connection hole is filled with metal such as copper, which has high electrical conductivity and thermal conductivity, from the rear surface of the first substrate 10 to the front surface. Here, the via 10f may be a through hole (through-hole via) that passes through the substrate 10 from the rear surface to the front surface. The through hole may be configured to have an inner surface covered with a material such as copper, which has electrical conductivity and thermal conductivity.

As illustrated in FIG. 3, the via 10f is disposed such that the via 10f is in contact with the ground layer 10d and is not in contact with a wire in the wiring layer 10b.

Further, an end of the via 10f on the front surface of the first substrate 10 is in contact with the heat dissipation member 14. In addition, the end of the via 10f and the heat dissipation member 14 are fixed to each other by, for example, a solder 15.

With the aforementioned configuration, it is possible to conduct the heat generated by the electronic component 12 to the ground layer 10d provided in the first substrate 10 and efficiently transfer the heat from the ground layer 10d to the heat dissipation member 14 via the via 10f. Thus, as described above, since many wires and vias 10f are provided near the electronic component 12 on the first substrate 10, the thermal conductivity from the electronic component 12 to the heat dissipation member 14 is higher than the thermal conductivity of the entire first substrate 10. Note that, as the number of the vias 10f in the substrate 10 increases, the thermal conductivity of the entire first substrate 10 improves, and a heat dissipation effect also becomes higher. Thus, it is suitable to provide the vias 10f as many as possible.

Note that, since many wires and vias (thermal vias) 10f which are formed of a material having high electrical conductivity and thermal conductivity are provided near the electronic component 12 on the first substrate 10, thermal conductivity of an area from the electronic component 12 to the heat dissipation member 14 is higher than the thermal conductivity of the entire first substrate 10. Accordingly, as described above, it is desirable that the material of the heat dissipation member 14 is constituted by a material having thermal conductivity higher than or equal to the thermal conductivity from the electronic component 12 on the first substrate 10 to the heat dissipation member 14.

### Configuration of Electronic Component

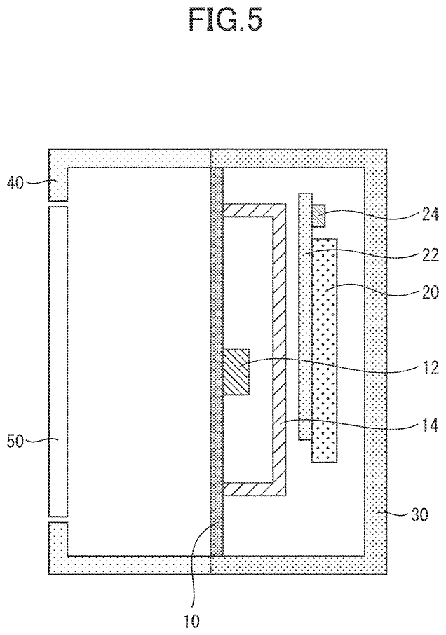

FIG. 4 is a sectional view of an example of the electronic component 12. The electronic component 12 may include an integrated circuit layer 12a in which at least an integrated circuit is formed and a memory layer 12b in which at least memory is formed and which is disposed further than the integrated circuit layer 12a from the first substrate 10. The integrated circuit layer 12a may be, for example, a system on chip (SOC). The integrated circuit layer 12a and the memory layer 12b are surrounded by a resin layer 12c having low thermal conductivity. Thus, in the aforementioned configuration, heat generated in the integrated circuit layer 12a is obstructed by the resin layer 12c and the memory layer 12b and is difficult to be dissipated from the side opposite to the first substrate 10.

However, with the configuration of the present embodiment, the heat generated by the electronic component 12 is able to be suitably removed from the first substrate 10 side. Thus, even the above-described electronic component is able to suppress a rise in temperature of the electronic device.

### Configuration of Electronic Device

FIG. 5 is a sectional view of the side surface of an example of the electronic device 1 of the disclosure. The electronic device 1 includes a housing that accommodates at least the first substrate 10 and the heat dissipation member 14 and a display panel 50 that is disposed on a surface side of the housing. The electronic device 1 dissipates heat of the electronic component 12 from a portion of the housing, which is disposed on a side opposite to the display panel 50. That is, the heat dissipation member 14 may be disposed on a side of the first substrate 10 opposite to the display panel 50.

As illustrated in FIG. 5, the electronic device 1 according to the present example includes the housing 30 as a first housing and further includes a housing 40 as a second housing. The material of the second housing 40 may be similar to the material constituting the housing 30. As the material of the first housing 30 and the second material 40, metal, a resin, and other materials may be used. Moreover, an opening part is formed in the second housing 40, and the display panel 50 is disposed in the opening portion.

Note that, although no component is illustrated on a second housing 40 side of the first substrate 10 in FIG. 5, the present embodiment is not limited thereto, and the electronic device 1 according to the present example may include one or more components on the second housing 40 side of the first substrate 10.

With the aforementioned configuration, the heat generated by the electronic component 12 is able to be dissipated in a wide range from the first housing 30 (the right side in FIG. 5) through the heat dissipation member 14. It is therefore possible to dissipate the heat from the first housing 30, which ordinarily serves as a grip portion for a user, without generating a heat spot having excessively high temperature. In this manner, according to the aforementioned example, it is possible to suppress generation of the heat spot having excessively high temperature in the first housing 30 on a grip portion side and suitably dissipate the heat generated by the electronic component 12.

### Disposing Position of Thermistor and Design of Electronic Device

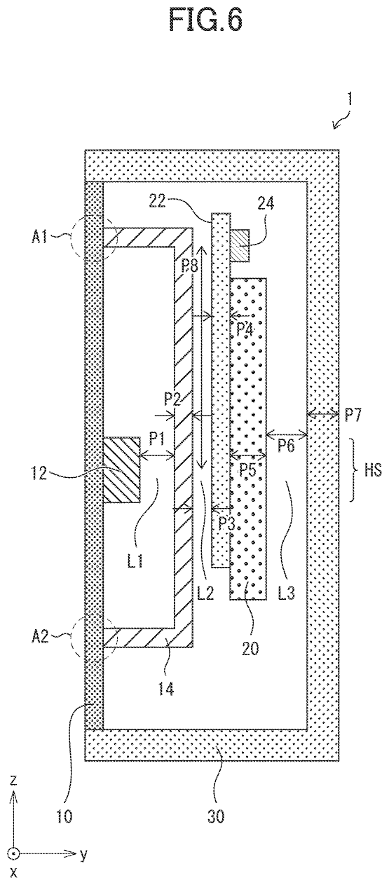

A disposing position of the thermistor 24 and design of the electronic device 1 according to the present embodiment will be described below in detail from the viewpoint of thermal resistance and thermal conduction with reference to FIG. 6.

As described above, the electronic device 1 includes the heat dissipation member 14 that covers the first substrate 10 with the first heat insulation layer L1 in between, the housing 30 that accommodates at least the first substrate 10 and the heat dissipation member 14, and the second substrate 22 that faces the heat dissipation member 14 across the second heat insulation layer L2 in the housing 30, and the thermistor 24 is disposed on the second substrate 22.

Accordingly, with the electronic device 1, it is possible to accurately calculate the temperature of the housing 30 by referring to the temperature detected by the thermistor 24.

Furthermore, the electronic device 1 according to the first embodiment is designed such that thermal resistance and heat capacity of a region from the electronic component 12 to a heat dissipation portion of the housing 30 are substantially identical to thermal resistance and heat capacity of a region from the electronic component 12 to the thermistor 24.

In other words, the thermistor 24 is disposed at a disposing position such that thermal resistance RH and heat capacity CH of the region from the electronic component 12 to the heat dissipation portion of the housing 30 and thermal resistance RT and heat capacity CT of the region from the electronic component 12 to the thermistor 24 satisfy

RH≈RT (expression 1)

CH≈CT (expression 2).

Here, in the present embodiment, it can be considered that expression 1 is satisfied when a difference between RH and RT is, for example, within about 10 percent. Moreover, it can be considered that expression 2 is satisfied when a difference between CH and CT is, for example, within about 10 percent.

However, It is desirable that the difference between RH and RT is within about 5 percent and that the difference between CH and CT is within about 5 percent.

FIG. 6 is a view for explaining heat capacity and thermal resistance in the electronic device 1. Reference numerals P1 to P7 illustrated in FIG. 6 indicate the following meanings.

P1: thickness of first heat insulation layer L1
P2: thickness of heat dissipation member 14
P3: thickness of second heat insulation layer L2
P4: thickness of second substrate 22
P5: thickness of holding member 20
P6: thickness of third heat insulation layer L3
P7: thickness of housing 30

Note that the “thickness” in the above description means a thickness in a direction normal to the first substrate 10.

In the electronic device 1, one or some of the aforementioned parameters P1 to P7 are adjusted such that expression 1 and expression 2 are satisfied.

Furthermore, in the electronic device 1, together with or instead of one or some of the aforementioned parameters P1 to P7, the material of the first substrate 10, the material of the heat dissipation member 14, the material of the second substrate 22, the material of the holding member 20, and the material of the housing 30 are adjusted such that expression 1 and expression 2 are satisfied.

With the electronic device 1 configured in this manner, the thermal resistance and the heat capacity of the region from the electronic component 12 to the heat dissipation portion of the housing 30 are substantially identical to the thermal resistance and the heat capacity of the region from the electronic component 12 to the thermistor 24, and it is therefore possible to accurately control the temperature of the housing 30 by referring to the temperature detected by the thermistor 24.

### Second Embodiment

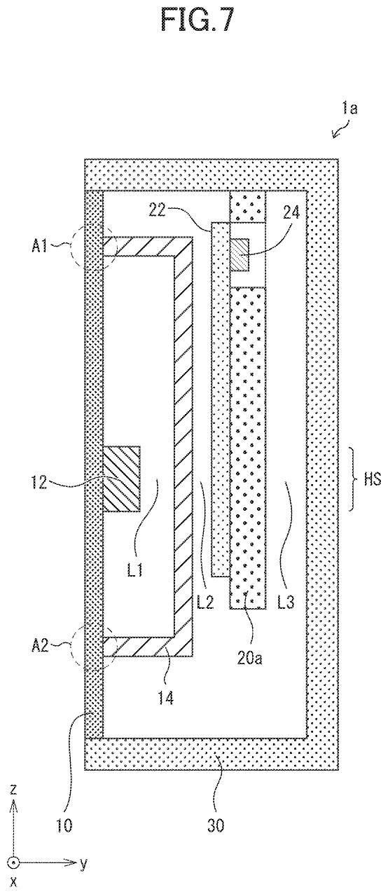

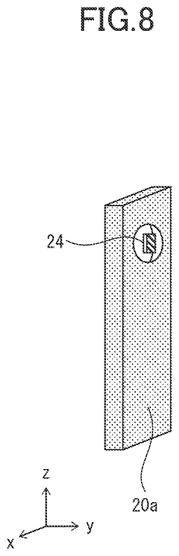

Next, a second embodiment will be described in detail with reference to FIGS. 7 and 8. Members that have been already described in the embodiment above will be given the same reference numerals, and description thereof will be omitted.

FIG. 7 is a sectional view of a portion of an electronic device 1a according to the present embodiment. As illustrated in FIG. 7, the electronic device 1a includes a holding member 20a instead of the holding member 20 provided in the electronic device 1 according to the first embodiment. The other configurations of the electronic device 1a are similar to those of the electronic device 1. FIG. 8 is a perspective view illustrating the holding member 20a and the thermistor 24.

As illustrated in FIGS. 7 and 8, an opening is formed in the holding member 20a, and the thermistor 24 is disposed in the opening. Here, the thermistor 24 is disposed such that the thermistor 24 is not in contact with an internal circumference of the opening. That is, the thermistor 24 is disposed apart from the holding member 20a similarly to the thermistor 24 in the first embodiment.

Accordingly, the thermistor 24 is less likely to be affected by a change in temperature of the holding member 20a, and it is therefore possible to more suitably control the temperature of the housing 30 by referring to the temperature detected by the thermistor 24.

### Conclusion

### Aspect 1

An electronic device of an aspect of the disclosure includes: an electronic component serving as a heat source; a first substrate on which the electronic component is disposed; a heat dissipation member that covers, with a first heat insulation layer in between, an area including a region of the first substrate, at which the electronic component is disposed, and being on a front side or a rear side of the first substrate; a housing that accommodates at least the first substrate and the heat dissipation member; a second substrate that faces the heat dissipation member across a second heat insulation layer in the housing; and a thermistor disposed on the second substrate.

With the aforementioned configuration, it is possible to accurately calculate temperature of the housing by referring to temperature detected by the thermistor.

### Aspect 2

In the electronic device of the aspect of the disclosure, the thermistor may be disposed on a surface of the second substrate, which is on a side opposite to the first substrate.

With the aforementioned configuration, it is possible to more suitably make the temperature detected by the thermistor close to the temperature of the housing.

### Aspect 3

In the electronic device of the aspect of the disclosure, a material of the heat dissipation member may contain copper.

With the aforementioned configuration, when copper whose electrical conductivity and thermal conductivity are both high and which is inexpensive is used for the heat dissipation member, it is possible to suppress a rise in temperature of the electronic device.

### Aspect 4

In the electronic device of the aspect of the disclosure, a holding member that holds the second substrate may be included, and the thermistor may be disposed apart from the holding member.

With the aforementioned configuration, the thermistor is less likely to be affected by a change in temperature of the holding member, and it is therefore possible to suitably manage temperature by referring to the temperature detected by the thermistor.

### Aspect 5

In the electronic device of the aspect of the disclosure, the second substrate may be a flexible printed circuit board and disposed on a surface of the holding member, which is on a side of the first substrate.

With the aforementioned configuration, it is possible to more suitably make the temperature detected by the thermistor close to the temperature of the housing.

### Aspect 6

In the electronic device of the aspect of the disclosure, a third heat insulation layer may be disposed between the holding member and the housing.

With the aforementioned configuration, it is possible to suppress an excessive rise in temperature of the housing.

### Aspect 7

In the electronic device of the aspect of the disclosure, thermal resistance and heat capacity of a region from the electronic component to a heat dissipation portion of the housing may be substantially identical to thermal resistance and heat capacity of a region from the electronic component to the thermistor.

With the aforementioned configuration, it is possible to accurately control the temperature of the housing by referring to the temperature detected by the thermistor.

### Aspect 8

In the electronic device of the aspect of the disclosure, a display panel disposed on a surface side of the housing may be included, and heat of the electronic component is dissipated from a portion of the housing, which is disposed on a side opposite to the display panel.

With the aforementioned configuration, it is possible to dissipate the heat in a wide range from a side on which a user ordinarily grips the electronic device, that is, a side opposite to the display panel. It is therefore possible to avoid the problem that temperature of a grip portion for the user becomes high, for example.

The present disclosure contains subject matter related to that disclosed in Japanese Priority Patent Application JP 2020-023828 filed in the Japan Patent Office on Feb. 14, 2020, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An electronic device comprising:
an electronic component serving as a heat source;
a first substrate on which the electronic component is disposed;
a heat dissipation member that covers, with a first heat insulation layer in between, an area including a region of the first substrate, at which the electronic component is disposed, and being on a front side or a rear side of the first substrate;
a housing that accommodates at least the first substrate and the heat dissipation member;
a second substrate that faces the heat dissipation member across a second heat insulation layer in the housing; and
a thermistor disposed on the second substrate.

2. The electronic device according to claim 1, wherein the thermistor is disposed on a surface of the second substrate, which is on a side opposite to the first substrate.

3. The electronic device according to claim 1, wherein a material of the heat dissipation member contains copper.

4. The electronic device according to claim 1, further comprising
a holding member that holds the second substrate, wherein
the thermistor is disposed apart from the holding member.

5. The electronic device according to claim 4, wherein
the second substrate is
a flexible printed circuit board, and
disposed on a surface of the holding member, which is on a side of the first substrate.

6. The electronic device according to claim 5, wherein
a third heat insulation layer is disposed between the holding member and the housing.

7. The electronic device according to claim 1, wherein
thermal resistance and heat capacity of a region from the electronic component to a heat dissipation portion of the housing are substantially identical to thermal resistance and heat capacity of a region from the electronic component to the thermistor.

8. The electronic device according to claim 1, further comprising
a display panel disposed on a surface side of the housing, wherein
heat of the electronic component is dissipated from a portion of the housing, which is disposed on a side opposite to the display panel.
